(19) United States
(12) Patent Application Publication
(10) Pub. No.: US 2023/0238597 A1
(43) Pub. Date: Jul. 27, 2023

(54) ENERGY STORAGE SYSTEM

(71) Applicant: SAMSUNG SDI CO., LTD., Yongin-si (KR)

(72) Inventors: Sung Koo KANG, Yongin-si (KR); Jae Pil EOM, Yongin-si (KR); Jeong Keun PARK, Yongin-si (KR); Jea Won SEO, Yongin-si (KR); Hyung Hoon LIM, Yongin-si (KR)

(21) Appl. No.: 18/100,677

(22) Filed: Jan. 24, 2023

(30) Foreign Application Priority Data
Jan. 27, 2022 (KR) 10-2022-0012601

(51) Int. Cl. H01M 10/48; H01M 10/613; H01M 10/63

(52) U.S. Cl. CPC H01M 10/486; H01M 10/613; H01M 10/482; H01M 10/63

(57) ABSTRACT

An energy storage system includes a rack having a space inside, a plurality of modules in the space of the rack, each of the plurality of modules including a plurality of battery cells arranged in one direction therein, and a sensing line along one side of the plurality of modules.

### CROSS-REFERENCE TO RELATED APPLICATION

This application claims priority to and the benefit of Korean Patent Application No. 10-2022-0012601, filed on Jan. 27, 2022, in the Korean Intellectual Property Office, the contents of which in its entirety are herein incorporated by reference.

### BACKGROUND

### 1. Field

The present disclosure relates to an energy storage system capable of accurately detecting a module where an event has occurred and injecting a fire extinguishing agent.

### 2. Description of the Related Art

An energy storage system may be linked with a renewable energy system, e.g., a solar cell, and may be configured to store power when electric power demand is low and to use the stored power at a time when electric power demand is high. The energy storage system may include an apparatus having a large number of battery cells composed of secondary batteries.

For example, an energy storage system may be configured such that the battery cells are received in multiple trays, which are received in a rack, and the multiple racks may be received in a container box. Since the energy storage system includes a large number of battery cells, it may have high capacity and high output.

### SUMMARY

An energy storage system according to an embodiment of the present disclosure may include a rack having a space inside; a plurality of modules accommodated in the rack and including a plurality of battery cells arranged in one direction therein; and a sensing line formed along one side for the plurality of modules, respectively.

The sensing line may be disposed in the same direction as one direction in which the plurality of battery cells are arranged in the plurality of modules.

In addition, the sensing line may be arranged in alternating directions for the plurality of modules positioned vertically in the rack.

In addition, the sensing line may be configured as a constant-temperature sensing linear sensor.

In addition, the sensing line may have a wiring structure formed by twisting a steel wire coated with a temperature sensitive material.

In addition, power and ground lines may be connected to both ends of the sensing line.

In addition, a shunt resistor connected in series with the sensing line may exist between the power and ground lines, and a controller connected to the shunt resistor may be further provided.

In addition, the controller may receive a voltage of both ends of the shunt resistor as an input value.

In addition, a fire extinguishing system that is connected in parallel with the controller and receives a voltage of both ends of the shunt resistor as an input value may be further included.

In addition, the controller or the fire extinguishing system may apply a control signal to spray a fire extinguishing agent to the fire extinguishing device when the voltage across the shunt resistor is sensed.

### BRIEF DESCRIPTION OF DRAWINGS

Features will become apparent to those of skill in the art by describing in detail exemplary embodiments with reference to the attached drawings, in which:

FIG. 1 is a perspective view of an energy storage system according to an embodiment of the present disclosure.

FIG. 2 is a conceptual diagram of a method for installing a sensing line at a lower end of a rack in an energy storage system according to an embodiment of the present disclosure.

FIG. 3 is a structural diagram of a sensing line used in an energy storage system according to an embodiment of the present disclosure.

FIGS. 4A and 4B are conceptual diagrams of operations when an event occurs in an energy storage system according to an embodiment of the present disclosure.

FIGS. 5A and 5B are conceptual diagrams of operations when an event occurs in an energy storage system according to another embodiment of the present disclosure.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

As used herein, the term “and/or” includes any and all combinations of one or more of the associated listed items. In addition, it will be understood that when an element A is referred to as being “connected to” an element B, the element A can be directly connected to the element B or an intervening element C may be present therebetween such that the element A and the element B are indirectly connected to each other.

The terminology used herein is for the purpose of describing particular embodiments only and is not intended to be limiting of the disclosure. As used herein, the singular forms are intended to include the plural forms as well, unless the context clearly indicates otherwise. It will be further understood that the terms that the terms “comprise or include” and/or “comprising or including,” when used in this specification, specify the presence of stated features, numbers, steps, operations, elements, and/or components, but do not preclude the presence or addition of one or more other features, numbers, steps, operations, elements, components, and/or groups thereof.

It will be understood that, although the terms first, second, etc. may be used herein to describe various members, elements, regions, layers and/or sections, these members, elements, regions, layers and/or sections should not be limited by these terms. These terms are only used to distinguish one member, element, region, layer and/or section from another. Thus, for example, a first member, a first element, a first region, a first layer and/or a first section discussed below could be termed a second member, a second element, a second region, a second layer and/or a second section without departing from the teachings of the present disclosure.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the element or feature in the figures is turned over, elements described as “below” or “beneath” other elements or features would then be oriented “on” or “above” the other elements or features. Thus, the exemplary term “below” can encompass both an orientation of above and below.

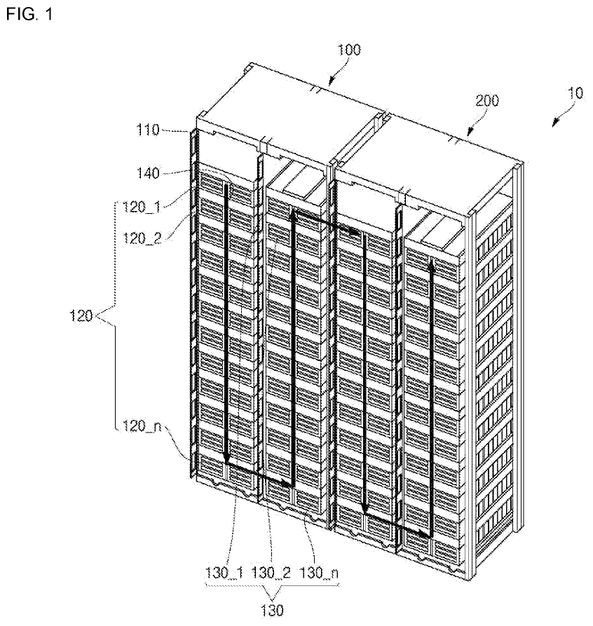

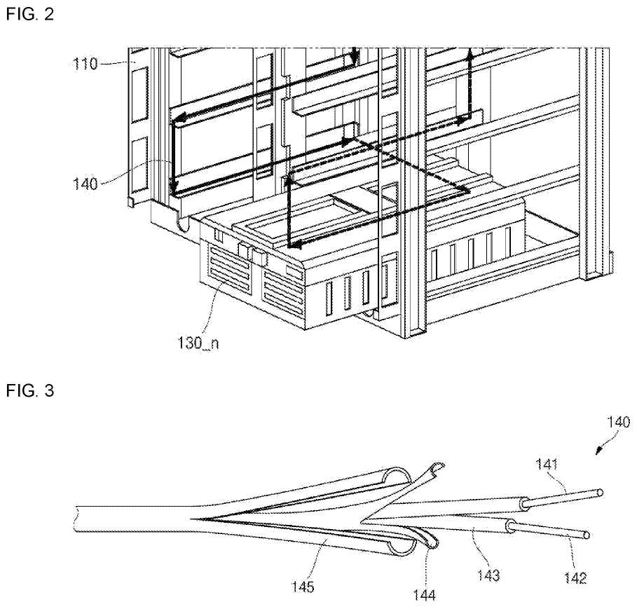

FIG. 1 is a perspective view showing a configuration of an energy storage system according to an embodiment of the present disclosure. FIG. 2 is an enlarged perspective view of a bottom part of the energy storage system of FIG. 1 illustrating a method for installing a sensing line according to an embodiment of the present disclosure.

First, referring to FIG. 1, an energy storage system 10 according to an embodiment of the present disclosure may include one or more racks, e.g., a first rack 100 and a second rack 200. For convenience, since the second rack 200 (or a subsequent rack) is the same as the first rack 100, only the first rack 100 will be mainly described.

As shown in FIG. 1, the first rack 100 may include a rack frame 110, a plurality of battery modules 120 and 130 accommodated in the rack frame 110, and a sensing line 140 formed along the plurality of battery modules 120 and 130.

The rack frame 110 may have accommodation spaces divided at regular intervals inside. The plurality of battery modules 120 and 130 may be accommodated in the rack frame 110. In addition, a circuit board including a module battery management system (BMS) may be coupled to a rear surface of the rack frame 110 to perform sensing and control of respective ones of the plurality of battery modules 120 and 130.

In addition, as will be described in detail below, the sensing line 140 may be formed along the rack frame 110 to sense an event occurring in the plurality of battery modules 120 and 130. For example, the sensing line 140 may be configured as a constant-temperature sensing linear sensor.

Inside each of the plurality of battery modules 120 and 130, a plurality of battery cells may be arranged and connected in various ways, e.g., in series, parallel, or series/parallel, according to a required output. For example, as illustrated in FIG. 1, the plurality of battery modules 120 and 130 may include a first sub-module 120 and a second sub-module 130 adjacent to each other along a horizontal direction, e.g., along a direction parallel to bottoms of the battery modules 120 and 130. For example, as illustrated in FIG. 1, the first sub-module 120 may include a plurality of battery cells stacked sequentially on top of each other, e.g., a first battery cell 120_1 to an n-th battery cell 120_n may be arranged on top of each other along a vertical direction perpendicular to the bottom of the first sub-module 120. For example, as illustrated in FIG. 1, the second sub-module 130 may include a plurality of battery cells stacked sequentially on top of each other, e.g., a first battery cell 130_1 to an n-th battery cell 130_n may be arranged on top of each other along the vertical direction. For example, as illustrated in FIG. 1, the first battery cell 120_1 of the first sub-module 120 and the first battery cell 130_1 of the second sub-module 130 may be aligned along the horizontal direction. In addition, the first and second sub-modules 120 and 130 may also be connected in various ways, e.g., in series, parallel, or series/parallel, respectively, so that a desired output may be generated in the first rack 100.

In each of the battery cells, an electrode assembly may be accommodated inside a case, and the electrode assembly may be configured to be wound, stacked, or laminated in a state in which a separator is placed between a positive electrode plate and a negative electrode plate having a region (e.g., a coating portion) coated with an active material. In addition, the top portion of the case may be sealed by a cap plate. In addition, in in each of the battery cells, electrode terminals electrically connected to uncoated portions of the positive electrode plate and the negative electrode plate may be exposed above the cap plate. In addition, a vent having a thickness smaller than that of other regions may be formed at an approximate center of the cap plate, and when the internal pressure of the battery cell rises above a reference level, the vent may be opened to discharge gas to the outside to prevent an explosion.

The sensing line 140 may be formed along a side of each of the plurality of battery modules 120 and 130. Accordingly, when an event, e.g., an opening of a vent or a fire, occurs in some of the battery cells of the plurality of battery modules 120 and 130, the position of the corresponding battery cell (in which the event occurs) may be sensed through the sensing line 140. Accordingly, an operation of spraying a fire extinguishing agent may be triggered, e.g., may accompany detection of an event.

Referring to FIG. 1, the arrangement of the sensing line 140 within the first rack 100 will be described. The sensing line 140 may be arranged to sequentially pass from the first battery cell 120_1 of the first sub-module 120 positioned at the topmost of a first side of the first rack 100 to the n-th battery cell 120_n of the first sub-module 120 positioned at the bottommost of the first side of the first the first rack 100. In addition, the sensing line 140 may be arranged to sequentially pass from the n-th battery cell 130_n of the second sub-module 130 positioned at the bottommost of a second side of the first rack 100 to the first battery cell 130_1 positioned at the topmost of the second side of the first rack 100. For example, as illustrated in FIG. 1, the same sensing line 140 may continuously extend along all the battery cells 120_1 to 120_n of the first sub-module 120, from the nth battery cell 120_n of the first sub-module 120 to the nth battery cell 130_n of the second sub-module 130, and along all the battery cells 130_1 to 130_n of the second sub-module 130. For example, as further illustrated in FIG. 1, the same sensing line 140 may continuously extend from the first rack 100 to the second rack 200. According to this arrangement, since the sensing line 140 passes through all the battery cells 120_1 to 120_n and 130_1 to 130_n of all the battery modules 120 and 130 constituting the first rack 100, when an event occurs in a battery cell in a specific module, the position of the corresponding battery cell may be sensed.

In detail, referring to FIG. 2, the sensing line 140 may be disposed along one surface, e.g., the lower surface, of each of the first and second sub-modules 120 and 130. As shown by a solid line in FIG. 2, when the sensing line 140 is disposed with respect to the first sub-module 120, the sensing line 140 may be formed along the front or rear end of the sub-module to then be disposed along the lower surface of the sub-module. Accordingly, the sensing line 140 may be arranged in the same direction as the direction in which the battery cell is arranged in the sub-module. In addition, in this state, when the sensing line 140 is coupled to a next sub-module, the sensing line 140 is again arranged along the front or rear end of the sub-module to then be disposed along the lower surface of the sub-module.

The arrangement shape of the sensing line 140 will be described on the basis of the direction within each sub-module. It is noted that while FIG. 1 illustrates a schematic direction of the sensing line 140 as a continuous, solid arrow, FIG. 2 illustrates a physical position of the sensing line 140 relative to the battery cells.

For example, referring to FIGS. 1 and 2, the sensing line 140 may be disposed on the lower surface of the first battery cell 120_1 of the first sub-module 120 in a direction from the front end to the rear end, may be disposed on the lower surface of the second battery cell 120_2 in a direction from the rear end to the front end, and may be disposed on the lower surface of the third battery cell 120_3 in a direction from the front end to the rear end. That is, on the basis of the lower surfaces of the battery cells 120_1 to 120_n of the first sub-module 120, the sensing line 140 may be arranged alternately from the front end to the rear end and from the rear end to the front end. However, even with this arrangement, the sensing line 140 passes through the lower surfaces of the respective battery cells 120_1 to 120_n in the same direction as the arrangement of the battery cells, and thus it may be possible to detect an event of a specific battery cell.

In addition, as shown in FIG. 2, the sensing line 140, the arrangement of which has been completed to the lower surface of the n-th battery cell 120_n that is the bottommost of the first sub-module 120, may be disposed along the lower surface of the n-th battery cell 130_n of the second sub-module 130 adjacent thereto. Thereafter, the wiring of the sensing line 140 in the first rack 100 may be completed by passing through all the modules positioned above the n-th battery cell 130_n and finally passing through to the lower surface of the first battery cell 130_1 at the top end. However, according to a selection of a user, the sensing line 140 may be further disposed in the same manner with respect adjacent racks, e.g., the second rack 200.

Hereinafter, a configuration of the sensing line 140 of an energy storage system according to an embodiment of the present disclosure will be described in more detail with reference to FIG. 3. FIG. 3 is a detailed structural diagram of the sensing line 140 according to an embodiment of the present disclosure.

Referring to FIG. 3, an operating principle of the sensing line 140 may use a twisting force in which intertwisted steel wires are attempted to return to a circular shape. That is, the sensing line 140 may include twisted steel wires that are covered with temperature sensitive materials 141 and 142, a protective tape 143 coating the temperature sensitive materials 141 and 142, an insulating molten material 144 covering the protective tape 143, and a flame retardant material 145.

In detail, the sensing line 140 may be configured such that exterior sides of steel wires are covered with the temperature sensitive materials 141 and 142. The temperature sensitive materials 141 and 142 may have very small heat-resistant performance and may be electrical insulating materials. The two insulated steel wires (which are coated with the temperature sensitive materials 141 and 142) may be twisted and wrapped with the protective tape 143, and exterior sides of the protective tape 143 may be coated with the insulating molten material 144 and the flame retardant material 145. In case of overheating or fire, in the sensing line 140, as the temperature sensitive materials 141 and 142 melt due to heat or flames, the twisted steel wires come into contact with each other, thereby causing a short circuit between the two wires and a short circuit current flow between the two wires.

For example, the temperature sensitive materials 141 and 142 may be set to be melted at a temperature of about 80 degrees to about 120 degrees. Accordingly, when a vent is opened or a fire occurs in a specific battery cell and reaches a corresponding temperature range, the temperature sensitive materials 141 and 142 in the specific battery cell (where temperature is increased due to an open vent of a fire) are melted, and the internal steel wires in the specific battery cell (where the temperature sensitive materials 141 and 142 are melted due to high temperature) contact each other, thereby causing a short circuit.

In addition, when the resistance of a steel wire up to a point of short-circuit of the sensing line 140 is known in advance from a controller, the controller may detect a position of the short-circuit by using a short-circuit current. For example, since the sensing line 140 is disposed along the lower surfaces of the battery cells 120_1 to 130_n in the first rack 100 and the second rack 200, each battery cell in each sub-module has a different distance from the controller. Therefore, the controller can identify accurate positions in the first rack 100 and the second rack 200 or the sub-modules 120 and 130, as well as the battery cells, through the short-circuit current.

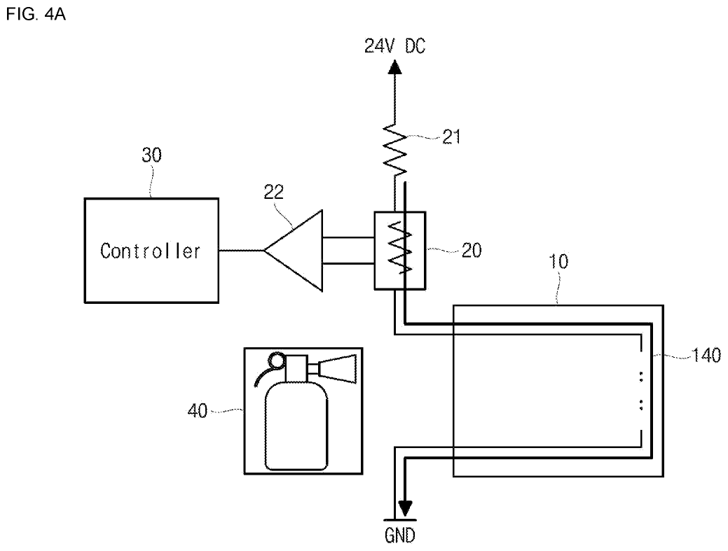

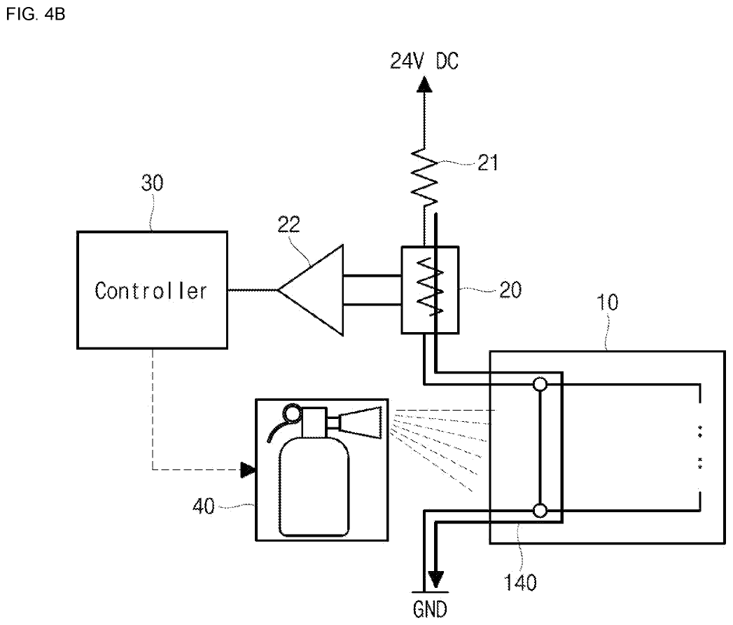

Hereinafter, the operation of a controller when an event occurs in an energy storage system according to an embodiment of the present disclosure will be described. FIGS. 4A and 4B are conceptual diagrams illustrating operations when an event occurs in an energy storage system according to an embodiment of the present disclosure.

Referring to FIG. 4A, the sensing line 140 in the energy storage system 10 may be connected between a power supply (24V DC), e.g., a power line, and a ground (GND), e.g., a ground line, through a shunt resistor 20 and a current limiting resistor 21. In addition, opposite ends, e.g., both ends, of the shunt resistor 20 may be connected to a controller 30 through an amplifier circuit 22. A fire extinguishing device 40 equipped with a fire extinguishing agent may be disposed inside or near the energy storage system 10.

In this state, the controller 30 may check the presence or absence of a short circuit current flowing through the sensing line 140 and the magnitude of the short circuit current in real time through the voltage across the shunt resistor 20. In a normal state, since no short-circuit current is generated in the sensing line 140, the voltage across the shunt resistor 20 may be displayed as 0 V.

Meanwhile, referring to FIG. 4B, when an event, e.g., an opening of a vent or a fire, in some of the battery cells in the energy storage system 10 occurs, the temperature sensitive materials 141 and 142 of the sensing line 140 are melted, and the steel wires come into contact with each other, causing a short circuit. In addition, a short-circuit current may be generated due to a potential difference between the power supply (24V DC) applied to both ends of the sensing line 140 and the ground (GND), so that a voltage may also be generated at both ends of the shunt resistor 20. As described above, the position of the short circuit of the sensing line 140 may change according to the position of the battery cell where the event occurs, and the resistance may change, and thus, the magnitudes of the short-circuit current and the voltage across the shunt resistor 20 may also vary. Therefore, the controller 30 may sense the position of the battery cell of the battery cells 120_1 to 130_n in the first rack 100 and the second rack 200 where the event has occurred through the voltage of the shunt resistor 20, e.g., the voltage across the shunt resistor 20 maybe an input value to the controller 30. In addition, the controller 30 may spray a fire extinguishing agent through the fire extinguishing device 40 to the corresponding position, and may further bypass the charge/discharge current for the corresponding battery cells 120_1 to 130_n, thereby stopping charging and discharging operations.

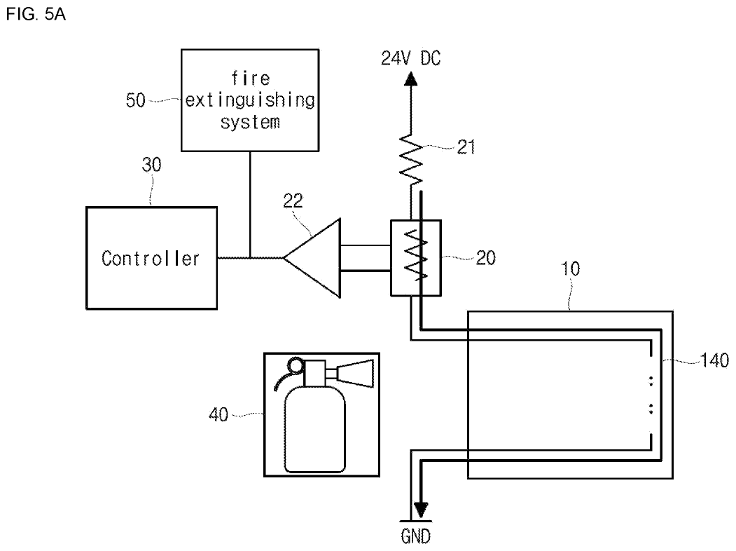

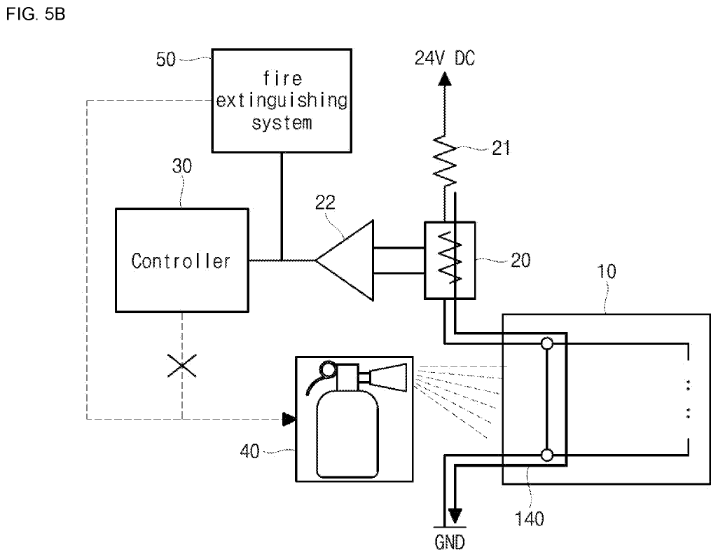

Hereinafter, the operation of a controller when an event occurs in an energy storage system according to another embodiment of the present disclosure will be described. FIGS. 5A and 5B are conceptual diagrams illustrating operations when an event occurs in an energy storage system according to another embodiment of the present disclosure.

Referring to FIG. 5A, in an energy storage system according to another embodiment of the present disclosure, the controller 30 and a separate fire extinguishing system 50 may be provided, and the fire extinguishing system 50 may branch and receive an output signal of the amplifier circuit 22 connected to the shunt resistor 20. Therefore, the fire extinguishing system 50 is connected in parallel with the controller 30, and thus, can operate independently of the controller 30.

Meanwhile, referring to FIG. 5B, when a normal operation is not enabled in the controller 30 due to an internal error or malfunction, the fire extinguishing system 50 independently applies a control signal to the fire extinguishing device 40. Thus, the fire extinguishing device 40 sprays the fire extinguishing agent to a battery cell in which an event occurred. Therefore, through such a double operation, when an event occurs in a battery cell, at least spraying of a fire extinguishing agent may be performed, thereby preventing a chain explosion or fire from occurring between battery cells constituting an energy storage system.

By way of summation and review, due to a structure of the energy storage system, when a fire occurs, it may be difficult to extinguish the fire. Accordingly, a technology for increasing the safety of the energy storage system may be required.

Therefore, embodiments provide an energy storage system capable of accurately detecting a module where an event has occurred and injecting a fire extinguishing agent. That is, as described above, in the energy storage system according to embodiments, a sensing line is disposed on one surface of each module, e.g., each battery cell, installed in a rack. This, when an event occurs in a battery cell in a module, the position of the corresponding module and battery cell can be accurately sensed.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An energy storage system, comprising:
a rack having a space inside;
a plurality of modules in the space of the rack, each of the plurality of modules including a plurality of battery cells arranged in one direction therein; and
a sensing line along one side of the plurality of modules.

2. The energy storage system as claimed in claim 1, wherein the sensing line extends in a same direction as the one direction of the plurality of battery cells.

3. The energy storage system as claimed in claim 1, wherein the plurality of battery cells are positioned vertically in the rack, the sensing line being arranged in alternating directions for the plurality of battery cells.

4. The energy storage system as claimed in claim 1, wherein the sensing line is configured as a constant-temperature sensing linear sensor.

5. The energy storage system as claimed in claim 1, wherein the sensing line includes a wiring structure having a twisted steel wire coated with a temperature sensitive material.

6. The energy storage system as claimed in claim 1, wherein opposite ends of the sensing line are electrically connected to a power line and a ground line, respectively.

7. The energy storage system as claimed in claim 6, further comprising:
a shunt resistor connected in series with the sensing line, the shunt resistor being connected between the power line and the ground line; and
a controller connected to the shunt resistor.

8. The energy storage system as claimed in claim 7, wherein the controller is configured to receive a voltage of both ends of the shunt resistor as an input value.

9. The energy storage system as claimed in claim 8, further comprising a fire extinguishing system connected in parallel with the controller, the fire extinguishing system being configured to receive the voltage of both ends of the shunt resistor as an input value.

10. The energy storage system as claimed in claim 8, wherein the controller is configured to apply a control signal to spray a fire extinguishing agent when a voltage across the shunt resistor is sensed.
